(19) United States
(12) Patent Application Publication
(10) Pub. No.: US 2004/0029361 A1
(43) Pub. Date: Feb. 12, 2004

(54) Method for producing semiconductor modules and a module produced according to said method

(76) Inventors: Marcel Heerman, Merelbeke (BE); Jozef Van Puymbroeck, Oostkamp (BE)

Correspondence Address: HARNESS, DICKEY & PIERCE, P.L.C., P.O.BOX 8910, RESTON, VA, 20195, US

(21) Appl. No.: 10/433,121

(22) PCT Filed: Nov. 29, 2001
(86) PCT No.: PCT/DE01/04489

(30) Foreign Application Priority Data
Nov. 29, 2000 (DE) 100 59 178.7

(51) Int. Cl. H01L 21/44; H01L 21/48; H01L 21/50

(52) U.S. Cl. 438/460; 438/121; 438/124

(57) ABSTRACT

According to the invention, the connection side of an undivided semiconductor wafer (1) is directly connected to a thermoplastic film (2), whose thermal expansion coefficient is approximately as low as that of the semiconductor material. Protuberance (21) are moulded onto the exposed underside of the film (2) by a hot embossing process, said protuberances acting as elastic external connections (25) and being connected in a conductive manner to internal connections (24) or to the wafer terminal elements (11) via passages (22). Individual semiconductor modules or packages that can be contacted on a printed circuit board by means of the plastic protuberances (21) are produced by dividing the finished contacted wafer. Said method allows semiconductor chips to be contacted on an intermediate support and the intermediate support to be contacted on a printed circuit board in a simple manner, ensuring a temperature-resistant connection between the semiconductor and the printed circuit board, without additional compensatory materials.

The invention relates to a method for producing semiconductor modules from a wafer containing at least one semiconductor component.

The increasing miniaturization of integrated circuits is giving rise to the problem of accommodating more and more electrical connections between the actual semiconductor and a circuit base, i.e. a printed circuit board, in a very confined space. The finer the structures of the semiconductor chip and of the connecting conductors, however, the greater the risk to them from differences in the expansion of the materials involved, in particular of the semiconductor body on the one hand and of the plastic printed circuit board on the other.

A key role in the contacting of semiconductor chips is played by the intermediate support or interposer, by means of which one or more chips are connected to a module or even package, said module or package then being contacted on the circuit base. Depending on the material from which the intermediate support is made, its thermally caused expansion relative to the semiconductor and/or relative to the circuit board has to be compensated for. Various measures in this regard, ranging from flexible conducting elements to elastic spacers, are already known.

In BGA (ball grid array) technology, the underside of an intermediate support is planarly furnished with pads which enable surface mounting on a printed circuit board. The pads act here on the one hand as electrical connections and on the other hand as spacers compensating for expansion between the different materials, namely the intermediate support and the printed circuit board. The semiconductor chip can be attached to the top side of the intermediate support and contacted for example by means of bonding wires. Flip-chip mounting, wherein the connections of the uncased semiconductor are connected directly to conducting tracks on the top side of the intermediate support, is also known. In order in this case to establish a means of balancing expansion between the semiconductor body and the intermediate support, underfilling of the semiconductor is generally required, which makes an additional, complicated and expensive process step necessary, said step also ruling out the possibility of subsequent repair.

In PSGA (polymer stud grid array) technology, an injection-molded, three-dimensional substrate made from an electrically insulating polymer is used as an intermediate support, on the underside of which polymer protuberances co-formed in the injection-molding process are arranged in a planar manner (EP 0 782 765 B1). These polymer protuberances are furnished with a solderable end surface and thus form external connections which are connected via integrated conducting tracks to internal connections for a semiconductor component arranged on the substrate. The polymer protuberances act as elastic spacers for the module relative to a printed circuit board and are thus capable of compensating for differences in expansion between printed circuit board and intermediate support. The semiconductor component can be contacted on the top side of the intermediate support via bonding wires; however, contacting wherein the differing thermal expansion coefficients are analogously compensated for by means of polymer protuberances on the top side of the intermediate support is also possible.

Furthermore, WO 89/00346 A1 discloses a single-chip module in which the injection-molded three-dimensional substrate, made of an electrically insulating polymer, carries polymer protuberances molded on the underside, said protuberances being arranged in one or more rows along the perimeter of the substrate. A chip is arranged on the top side of the substrate; it is contacted by means of fine bonding wires and conducting tracks which are then for their part connected via plated-through holes to the external connections fashioned on the underside protuberances. In this design, the intermediate support exhibits a relatively large expansion.

The object of the present invention is to indicate a method for producing semiconductor modules from a wafer containing at least one semiconductor component, wherein direct contacting of the semiconductor element on an intermediate support and direct contacting of this intermediate support on a circuit base are possible such that the risk of temperature-caused stress damage is avoided without the intermediate connection of special compensatory elements.

This object is achieved according to the invention by means of the following process steps whose order can vary:

a) The connection side of a semiconductor wafer is directly connected to the top side of a thermoplastic film, whose thermal expansion coefficient is approximately as low as that of the semiconductor material;

b) flat internal connections composed of metal are fashioned on the top side of the film and connected to terminal elements of the wafer;

c) protuberances are molded onto the underside of the film by a hot embossing process, the end surfaces of said protuberances forming external connections;

d) passages are produced between the underside and the top side of the film;

e) a metal layer is deposited in the passages and on the underside of the film as well as on the protuberances and is patterned such that it forms conductor tracks from each of the external connections to the internal connections via the passages; and

f) the wafer, finished contacted with the film, is, if necessary, divided in a final step into individual semiconductor modules.

In the method according to the invention, a thermoplastic film with a low thermal expansion coefficient matching that of the semiconductor material is used as an intermediate support, protuberances for external contacting being molded on the underside of said film by means of a hot embossing process. Using a film composed of a single material as intermediate support, a temperature-resistant connection can thus be produced between the semiconductor itself, the intermediate support and the printed circuit board, since the contact protuberances can take up the differences in expansion between the film and the printed circuit board. The protuberances may project above the underside of the intermediate support or be fashioned by means of ring-shaped impressions as sunken protuberances whose end surfaces jut out only slightly or not at all from the underside of the intermediate support.

The wafer itself is in this case applied directly onto the film with approximately the same expansion coefficient and bonded directly onto the bearing surface so that additional conductors such as bonding wires, issuing from the edge of the semiconductor chip, are not needed, i.e. require neither space nor relevant work processes. It is also possible, by bonding inside the external contour of the individual chip, to connect the entire undivided semiconductor wafer to the film functioning as an intermediate support and not to divide it up until all the connecting and bonding steps have been completed.

In an advantageous embodiment of the method according to the invention, the following sequence of steps is applied:

a) the wafer is connected to the film;

c) the protuberances are molded onto the underside of the film by hot embossing;

d) the passages are produced below the terminal elements of the wafer in such a way that the terminal elements lie exposed in the passages;

e) the metal layer is then deposited on the underside of the film and in the passages, the internal connections being produced in the upper end region of the passages as a metal coating of the exposed wafer terminal elements, and the metal layer is then patterned on the underside of the film;

f) the chips of the wafer, or the modules formed with said chips, can then be divided up.

In this version of the method, it is also possible in step c) to produce the passages by a hot embossing process. However, the passages will preferably be produced by laser drilling; it can also be expedient when molding the passages by means of a hot embossing process to remove residues using a laser beam. A laser will in any case preferably be used for patterning the metal layer on the underside of the film.

In a modified version of the method, the process steps are carried out in the following sequence:

c) firstly, the protuberances are produced on the film by means of a hot embossing process;

a) the film is then connected to the wafer, preferably using a nonconducting bonding agent,

d) the passages are produced below the terminal elements of the wafer in such a way that said elements lie exposed in the passages;

e) the metal layer is deposited on the underside of the film and in the passages , the internal connections being produced in the upper end region of the passages in compliance with step b) as a metal coating on the exposed wafer terminal elements, and the metal layer on the underside of the film is then patterned to form conducting tracks; and

g) the wafer is divided.

In this case, too, the passages can optionally be molded by a hot embossing process or produced by laser drilling as in the preceding case.

A further modified process exhibits this sequence of steps:

c) the protuberances and optionally the passages are produced in the film by a hot embossing process;

d) the passages are, if necessary, drilled or cleaned;

e) a metal layer is produced on the underside and the top side of the film, including the passages and the protuberances, and patterned such that internal connections formed on the top side are each connected via the passages to a protuberance forming an external connection;

a) the wafer is connected to the film such that the wafer terminal elements are each conductively connected to an internal connection; and

f) the wafer is divided.

In this case, too, the passages will preferably be drilled or at least freed of residues by means of a laser. The wafer terminal elements can be bonded to the internal connections by means of a conductive bonding agent. In another advantageous embodiment, the wafer terminal elements can also be contacted by means of a pad applied onto the elements themselves or/and onto the internal connections.

A semiconductor module produced according to the inventive method is accordingly characterized by a semiconductor chip separated from a wafer, said semiconductor chip being fastened and directly bonded to an intermediate support separated from its film, conductive through-connectors by means of drilled passages between the top side and the underside of the intermediate support, protuberances molded onto the underside of the intermediate support, the end surfaces of said protuberances being conductively connected via the passages to the terminal elements of the chip, wherein the thermal expansion coefficient of the intermediate support is approximately the same as that of the semiconductor chip.

The invention is described in detail below in exemplary embodiments using the drawings, in which:

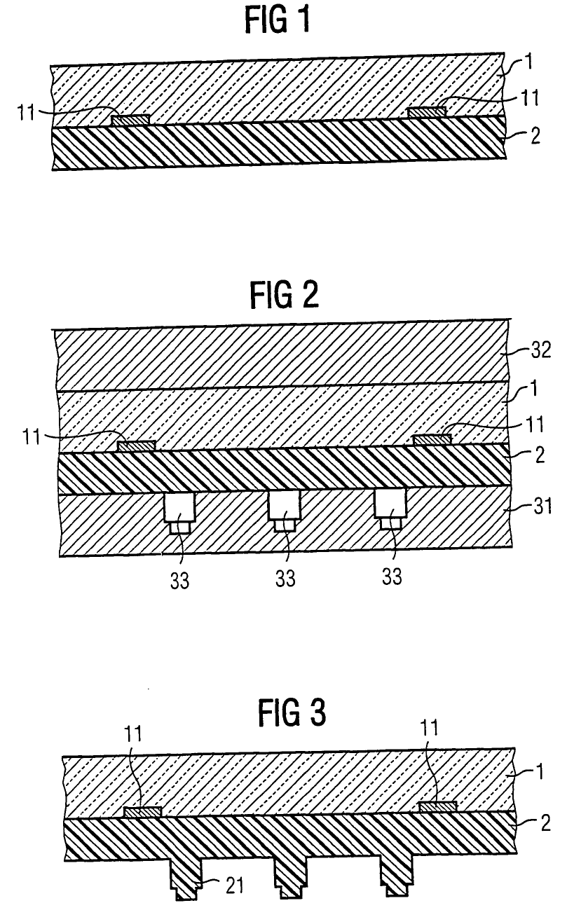

FIGS. 1 to 8 show the production according to the invention of a semiconductor module from a wafer, in accordance with a first sequence of process steps,

FIG. 9 shows the contacting onto a printed circuit board of a module produced according to the invention,

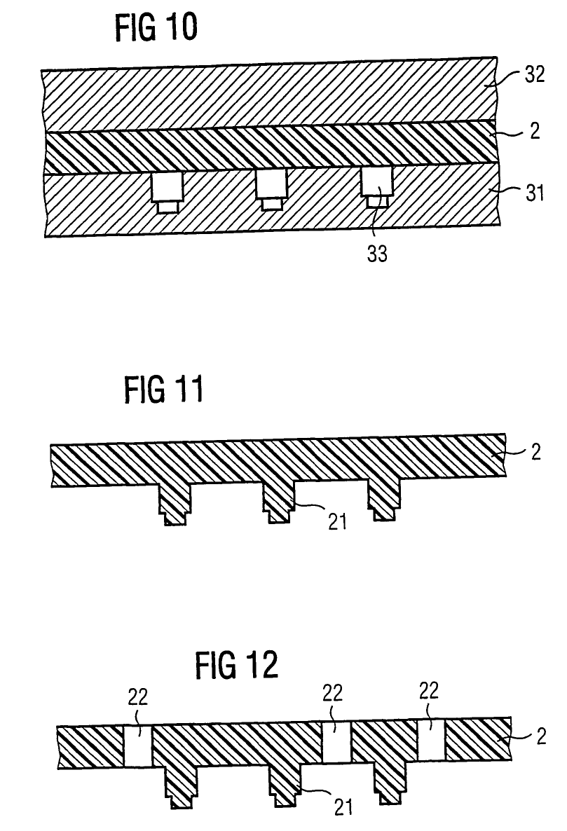

FIGS. 10 to 16 show the production according to the invention of a semiconductor module, in accordance with a second sequence of process steps, and

FIG. 17 shows the contacting onto a printed circuit board of a module produced according to the second embodiment.

The production method illustrated in FIGS. 1 to 8 for one or more semiconductor modules begins in a first step with a thermoplastic film 2 being applied, for example bonded, to the underside of a semiconductor wafer 1 with terminal elements (pads) 11. This film is preferably composed of LCP (liquid crystal polymer) which possesses a similarly low thermal expansion coefficient of, for example, 5 to 20 ppm as the silicon of the semiconductor wafer. The film preferably has a thickness of between 50 and 250 μm. Besides LCP, other materials can, however, also be used for the film, for example materials based on polytetrafluoroethylene, which is traded under the Teflon brand.

In a second step, the film is hot embossed. To this end, the wafer 1 connected to the film 2 is placed between the mold parts 31 and 32 of an embossing mold, recesses 21 being provided in the mold part 31, each recess enabling a protuberance to be molded on the underside of the film 2 by means of the hot embossing process.

These protuberances 21 can be seen in FIG. 3 which shows the connection of the wafer 1 to the film 2 after the embossing mold has been removed. The protuberances 21 obtained in this way will preferably have a diameter of between 100 and 250 μm and a height of between 150 and 350 μm. They will later serve as elastic external connections in the semiconductor module.

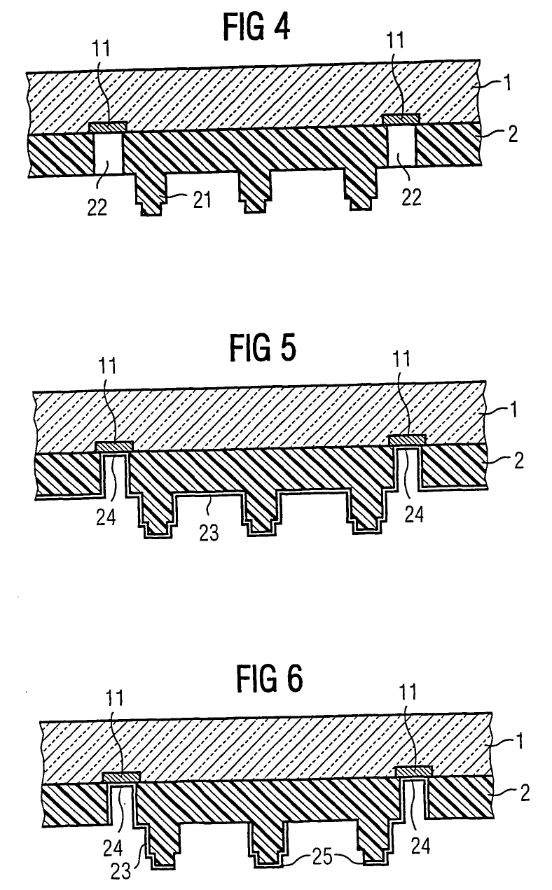

As FIG. 4 shows, in the next process step, passages 22 are drilled through the film from the underside of the film, in each case below the terminal elements 21 of the wafer, so that after the drilling, which is performed by means of a laser, the terminal elements 21 lie exposed in the passages 22. By metalizing the underside of the film 2, the inside walls of the passages 22 and the protuberances 21 are simultaneously coated with metal as per FIG. 5. In this process, internal connections 24 are also formed on the exposed areas of the terminal elements 11 of the semiconductor wafer, said internal connections thus being directly contacted to the wafer terminal elements. At the same time, this metalization layer forms metallic external connections 25 on the end surfaces of the protuberances 21.

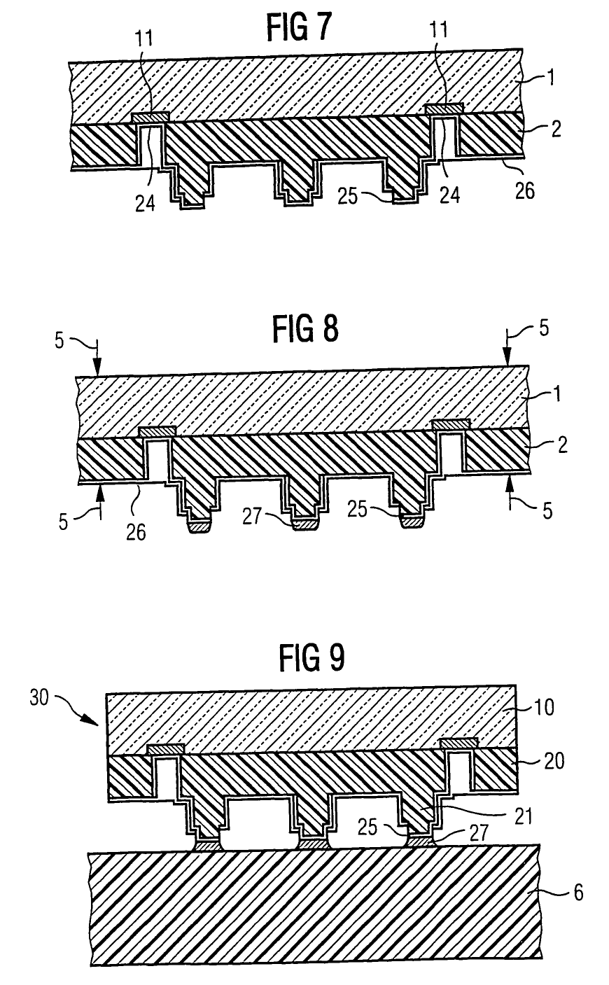

Unneeded metal areas on the underside of the film 2 are removed by laser patterning as per FIG. 6, so that only the connecting conductors between the internal connections 24 and the external connections 25 and optionally other conducting tracks remain. The underside of the film 2 is subsequently covered as per FIG. 7 with a solder resist 26, for example by means of spray-coating or electro-deposition, the external connections 25 being kept free. These external connections can be furnished as per FIG. 8 with an additional solder coating; the individual semiconductor modules are then separated, for example by sawing, at the separation lines indicated by arrows 5.

A semiconductor module 30 obtained in this way, consisting of a chip 10 and an intermediate support 20, can then, as per FIG. 9, be mounted on a printed circuit board 6 and soldered there.

FIGS. 10 to 16 show a somewhat different process produced by a modified sequence of steps. In this case, the film 2, the characteristics of which have already been described earlier, is placed alone in a hot embossing tool and embossed between the mould parts 31 and 32, the lower mold part 31 also in this case having recesses 33 by means of which protuberances 21 are molded onto the underside of the film (FIG. 11). Passages 22 are then introduced into the thus embossed film 2 by laser drilling as per FIG. 12. As previously mentioned, the passages could possibly also be produced in the hot embossing process.

In a further process step as per FIG. 13, metalization layers 23 and 28 are produced on the underside and on the top side, respectively, of the film 2, the walls of the passages also being metalized from top to bottom. Superfluous metal areas are removed by subsequent patterning of the metal layers 23 and 28 on the top side and underside, so that on the end faces of the protuberances internal connections 24 are retained on the top side and external connections 25 on the underside, and their connections via the passages 22, are retained in each case. Further conductor tracks are patterned as required.

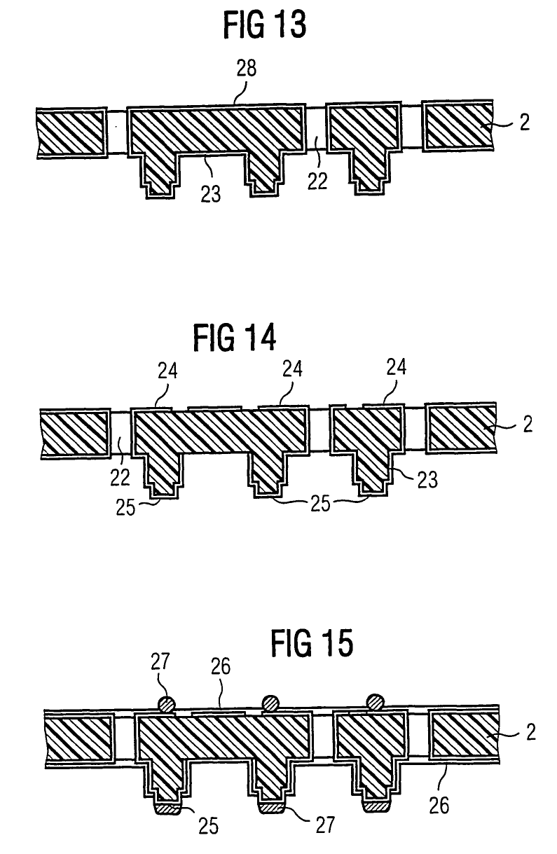

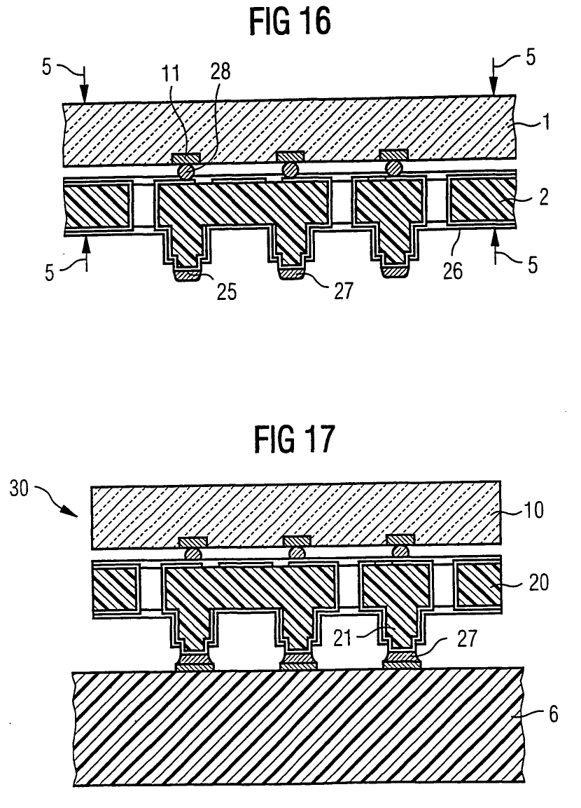

The film is then coated on the top side and on the underside with solder resist 26, the internal connections 24 on the top side and the external connections 25 on the protuberances being kept free. Methods such as spray-coating or the ED (electro-deposition) resist method come into consideration when applying the solder resist to the surface interspersed with protuberances. A solderable and/or bondable layer 27 is then applied in each case to the protuberances or the external connections 25 (FIG. 15), if required also in the form of pads.

As shown in FIG. 6, the semiconductor wafer 1 is now mounted on the film 2 which has been processed and patterned in this way such that the wafer's terminal elements 11 in each case lie on the internal connections 24 so that said elements can be soldered or bonded by means of a conductive bonding agent to said connections. Previously applied pads 28 for example can be used for soldering.

As in the preceding example, the semiconductor modules 30 are then separated along the separation lines 5 (FIG. 16) and soldered as per FIG. 17 onto a printed circuit board 6.

A mixed form of the two processes shown is also possible: thus, the film 2 could firstly be hot embossed as per FIGS. 10 and 11 and then connected directly to the underside of the semiconductor wafer 1 such that a connection as per FIG. 3 is produced. This would then be followed by a process sequence, as has already been described using FIGS. 4 to 8. In this case, the semiconductor wafer would not be exposed to the pressure of the embossing tool; the patterning and contacting would, however, otherwise proceed as previously described.

1. A method for producing semiconductor modules from a semiconductor wafer containing at least one semiconductor component by means of the following steps, the order of which can differ:
a) the connection side of a semiconductor wafer (1) is directly connected to the top side of a thermoplastic film (2), whose thermal expansion coefficient is approximately as low as that of the semiconductor material;
b) flat internal connections (24) made of metal are fashioned on the top side of the film (2) and connected to terminal elements (11) of the wafer (1);
c) protuberances (21) are molded onto the underside of the film (2) by a hot embossing process, the end surfaces of said protuberances forming external connections (25);
d) passages (22) are produced between the underside and the top side of the film;
e) a metal layer (23) is deposited in the passages (22) and on the underside of the film (2) as well as on the protuberances (21) and is patterned such that it forms conductor tracks from each of the external connections (25) via the passages (22) to the internal connections (24) and
f) the wafer (1), finished contacted with the film (2), is divided in a final step into individual semiconductor modules (10).

2. A method according to claim 1, characterized by the following sequence of process steps:
a) the wafer (1) is connected to the film (2);
c) the protuberances (21) are molded onto the underside of the film by hot embossing the interconnection of wafer (1) and film (2);
d) the passages (22) are produced in the area below each of the terminal elements (11) of the wafer such that the terminal elements (11) lie exposed in the passages (22);
e) the metal layer (23) is deposited on the underside of the film (2) and in the passages (22), the internal connections (24) being produced in the upper end region of the passages in accordance with step b) as a metal coating on the exposed wafer terminal elements (11), and the metal layer (23) is then patterned onto the underside of the film (2); and
f) the wafer is divided.

3. A method according to claim 2,
characterized in that the passages (22) are formed wholly or in part in step c) by hot embossing.

4. A method according to claim 2 or 3,
characterized in that the passages (22) are produced by laser drilling or cleaned by laser processing of residues of the hot embossing process.

5. A method according to claim 1,
characterized by the following sequence of individual steps:
b) firstly, the protuberances (21) are produced on the film (2) by hot embossing;
a) the embossed film (2) is connected to the wafer (1);
d) the passages (22) are produced below the terminal elements (11) of the wafer (1) in such a way that these terminal elements lie exposed in the passages (22);
e) the metal layer is deposited on the underside of the film (2) and in the passages (22), the internal connections (24) being produced in the upper end region of the passages (22) in accordance with step b) as a metal coating on the exposed wafer terminal elements (11); the metal layer (23) is then patterned on the underside of the film (2); and
f) the wafer is divided.

6. A method according to claim 5,
characterized in that in step c) the passages (22) are molded at least in part by hot embossing.

7. A method according to claim 5 or 6,
characterized in that in step d) the passages (22) are produced by laser drilling or are cleaned by laser processing of residues of the embossing step c).

8. A method according to one of claims 5 to 7,
characterized in that in step a) the wafer (1) is connected by means of a non-conducting bonding agent to the film (2).

9. A method according to claim 1,
characterized by the following sequence of process steps:
c) the protuberances (21) and, where applicable, the passages (22) are produced in the film (2) by hot embossing;
d) the passages (22) are, if necessary, drilled or cleaned;
e) a metal layer (23;27) is produced on the underside and on the top side of the film (2), including the passages (22) and the protuberances (21), and patterned such that internal connections (24) formed on the top side are each connected via the passages (22) to a protuberance (21) forming an external connection (25);
a) the wafer (1) is connected to the film such that the wafer terminal elements (11) are each conductively connected to an internal connection (24); and
f) the wafer is divided.

10. A method according to claim 9,
characterized in that the passages (22) are drilled and/or cleaned by means of a laser.

11. A method according to claim 9 or 10,
characterized in that the wafer terminal elements (11) are bonded by means of a conductive bonding agent to the internal connections (24).

12. A method according to claim 9 or 10,
characterized in that the wafer terminal elements are contacted through pads (28) applied to the terminal elements themselves (11) and/or to the internal connections (24).

13. A method according to one of claims 1 to 12,
characterized in that the protuberances (21) are embossed prominently over the underside of the film.

14. A method according to one of claims 1 to 12,
characterized in that the protuberances are fashioned in a recessed manner by impressing ring-shaped grooves in the underside of the film

15. A semiconductor module produced using the method according to one of claims 1 to 14,
characterized by a semiconductor chip (10) separated from a wafer (1), said chip being fastened and directly contacted onto an intermediate support (20) separated from its film, conductive passages by means of through-holes (22) between the top side and the underside of the intermediate support, protuberances (21) molded onto the underside of the intermediate support (20), the end surfaces (25) of said protuberances being conductively connected via the passages (22) to the terminal elements (11) of the chip (10), the thermal expansion coefficient of the intermediate support (20) being approximately equal to that of the semiconductor chip (10).

16. A semiconductor module according to claim 15,
characterized in that the intermediate support (20) is composed of LCP.

17. A semiconductor module according to claim 15,
characterized in that the intermediate support is composed of a film based on polytetrafluoroethylene.

18. A semiconductor module according to one of claims 15 to 17,
characterized in that the intermediate support (20) has a thickness of between 50 and 250 μm.

19. A semiconductor module according to one of claims 15 to 18,
characterized in that the protuberances (21) have a diameter of between 100 and 250 μm and a height of between 150 and 350 μm.
